(19) United States
(12) Patent Application Publication
(10) Pub. No.: US 2025/0275440 A1
(43) Pub. Date: Aug. 28, 2025

(54) DISPLAY APPARATUS HAVING A PIXEL LENS

(71) Applicant: LG Display Co., Ltd., Seoul (KR)

(72) Inventors: Yong Ku LEE, Paju-si (KR); Se Wan OH, Paju-si (KR); Seok Ho KI, Paju-si (KR); Young Bok LEE, Paju-si (KR)

(21) Appl. No.: 18/970,442

(22) Filed: Dec. 5, 2024

(30) Foreign Application Priority Data
Feb. 26, 2024 (KR) 10-2024-0027411

(51) Int. Cl. H10K 59/80; H10K 59/122

(52) U.S. Cl. CPC H10K 59/879; H10K 59/122

(57) ABSTRACT

A display apparatus is provided. The display apparatus can include a light-emitting device on an emission area of a device substrate. A first barrier pattern, an optical insulating layer, a second barrier pattern and a pixel lens can be disposed on an encapsulation structure covering the light-emitting device. The optical insulating layer can be disposed between the first barrier pattern and the second barrier pattern. The first barrier pattern and the second barrier pattern can extend in a first direction. The pixel lens can be disposed on the optical insulating layer. A plane of an end portion of the pixel lens toward the first direction can have a curved shape. Thus, in the display apparatus, a viewing angle can be limited, and the overall luminance can be improved.

### CROSS-REFERENCE TO RELATED APPLICATIONS

This application claims the benefit of Korean Patent Application No. 10-2024-0027411, filed on Feb. 26, 2024, which is hereby incorporated by reference as if fully set forth herein.

### BACKGROUND

### Technical Field

The present disclosure relates to a display apparatus in which a light-emitting device and a pixel lens are stacked on each pixel area.

### Description of the Related Art

Generally, a display apparatus provides an image to a user. For example, the display apparatus can include light-emitting devices. Each of the light-emitting devices can emit light displaying a specific color. For example, each of the light-emitting devices can include a first electrode, a light-emitting layer and a second electrode, which are sequentially stacked.

A travelling direction of light emitted from each light-emitting device can be limited. For example, in the display apparatus, barrier patterns can be stacked between emission areas in which the light-emitting devices are disposed. Each of the barrier patterns can include a material blocking light.

### BRIEF SUMMARY

A display apparatus incorporating barrier patterns can limit a viewing angle of the display apparatus. However, the inventors of the present disclosure have recognized that the light extraction efficiency of the display apparatus can be decreased by the barrier patterns. Accordingly, the present disclosure is directed to a display apparatus that substantially obviates one or more problems due to limitations and disadvantages of the related art.

Various embodiments of the present disclosure provide a display apparatus capable of limiting the viewing angle and increasing the light extraction efficiency.

Various embodiments of the present disclosure provide a display apparatus capable of maximizing the amount of the light provided to the user.

Additional advantages and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these and other advantages and in accordance with the spirit of the present disclosure, as embodied and broadly described herein, there is provided a display apparatus comprising a device substrate. The device substrate includes an emission area and a non-emission area. A light-emitting device is disposed on the emission area of the device substrate. A first barrier pattern is disposed on the light-emitting device. The first barrier pattern overlaps the non-emission area. An optical insulating layer is disposed on the light-emitting device and the first barrier pattern. The optical insulating layer overlaps the emission area and the non-emission area. A second barrier pattern and a pixel lens are disposed on the optical insulating layer. The second barrier pattern overlaps the first barrier pattern. The pixel lens includes a first lens region and a second lens region. The first lens region overlaps the emission area. The second lens region extends from the first lens region in a first direction. The first barrier pattern and the second barrier pattern extend in a direction. Each of an end portion of the second lens region and an end portion of the emission area toward the first direction includes a region disposed outside the first barrier pattern and the second barrier pattern. A plane of the end portion of the second lens region toward the first direction has a larger curvature than a plane of the end portion of the emission area toward the first direction.

The second lens region can include a same material as the first lens region.

A cross-section of the first lens region in the first direction can have a constant thickness. A cross-section of the second lens region in the first direction can have a curved shape. The maximum thickness of the cross-section of the second lens region in the first direction can be a same as the thickness of the cross-section of the first lens region in the first direction.

A length of the first lens region in a second direction perpendicular to the first direction can be constant. The maximum length of the second lens region in the second direction can be a same as the length of the first lens region in the second direction.

A plane of the emission area and a plane of the first lens region can have a bar shape extending in the first direction.

A side of the first lens region extending in the first direction can overlap the second barrier pattern.

The second barrier pattern can include a different material from the first barrier pattern.

The second barrier pattern can include a conductive material.

In another embodiment, there is provided a display apparatus comprising a device substrate. A bank insulating layer and a light-emitting device are disposed on the device substrate. The bank insulating layer defines an emission area. The light-emitting device is disposed in the emission area. A first barrier pattern and an optical insulating layer are disposed on the bank insulating layer. The first barrier pattern extends in a first direction. The optical insulating layer covers the first barrier pattern. The optical insulating layer extends onto the light-emitting device. A second barrier pattern and a pixel lens are disposed on the optical insulating layer. The second barrier pattern extends parallel to the first barrier pattern. The pixel lens overlaps the emission area. A size of the pixel lens is a greater than a size of the emission area. An end portion of the pixel lens and an end portion of the emission area toward the first direction are spaced apart from the first barrier pattern and the second barrier pattern. The maximum distance between the pixel lens and the emission area in the first direction is larger than the maximum distance between the pixel lens and the emission area in a second direction. The second direction is perpendicular to the first direction.

A length of the emission area in the second direction can be smaller than a length of the emission area in the first direction.

The pixel lens can include a first lens region and a second lens region. The first lens region overlaps the emission area. The second lens region is disposed side by side with the first lens region. The first lens region and the second lens region can include a region overlapping with the second barrier pattern. A portion of the first lens region overlapping with the second barrier pattern can have a smaller size than a portion of the second lens region overlapping with the second barrier pattern.

The second lens region can be in contact with the first lens region.

A plane of a portion of the second lens region overlapping with the second barrier pattern can have a curved shape.

The maximum length of the second lens region in the second direction can be 120% to 140% with respect to the maximum length of the first lens region in the first direction.

A plane of the pixel lens can have a shape that is symmetrical with respect to the center portion of the emission area.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to the embodiment of the present disclosure;

FIG. 3 is an enlarged view of K1 region in FIG. 1;

FIG. 4 is a view taken along I-I′ of FIG. 3;

FIG. 5 is a view taken along II-II′ of FIG. 3; and

FIGS. 6 to 12 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

It will be understood that, when a first element is referred to as being “on” a second element, although the first element can be disposed on the second element so as to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” can include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### EMBODIMENT

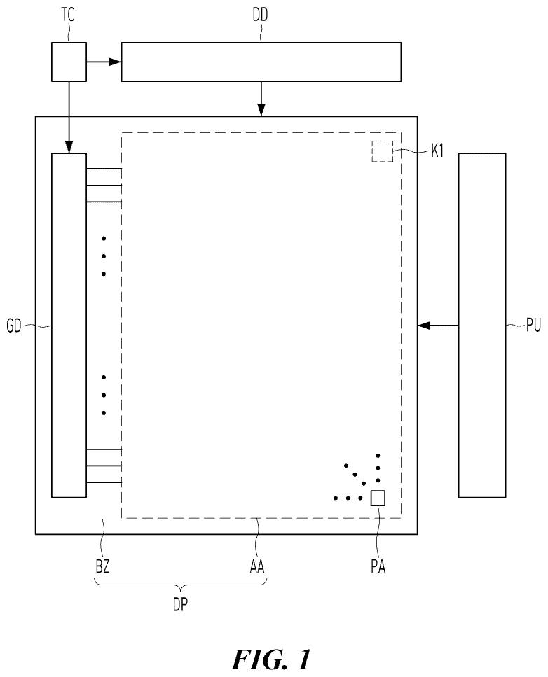

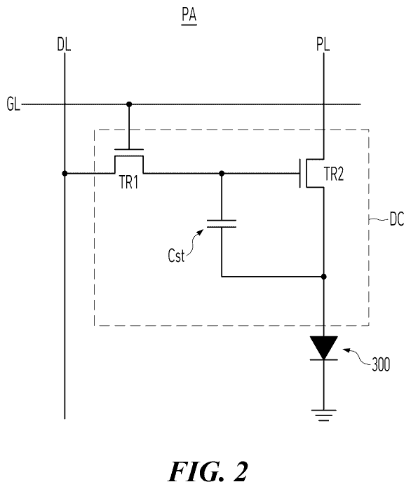

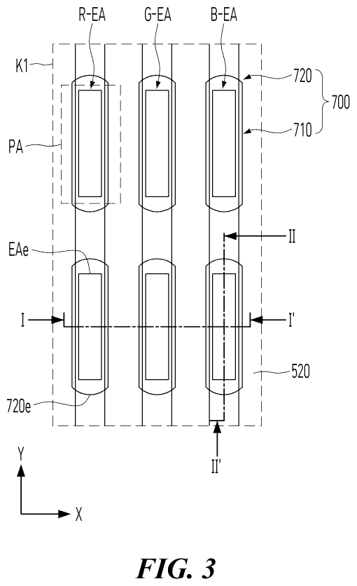

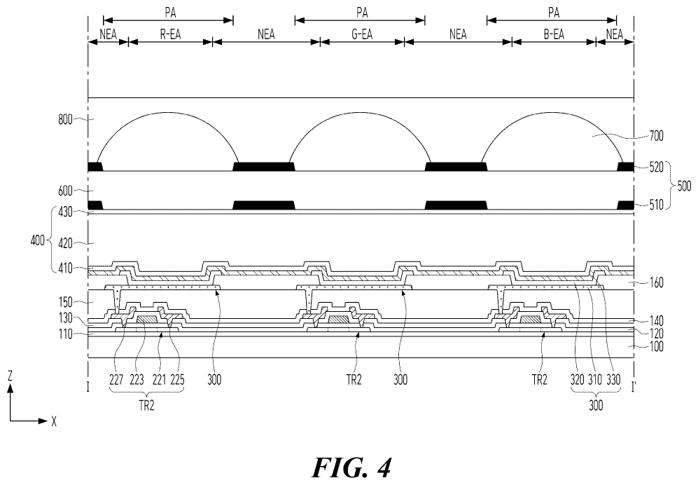

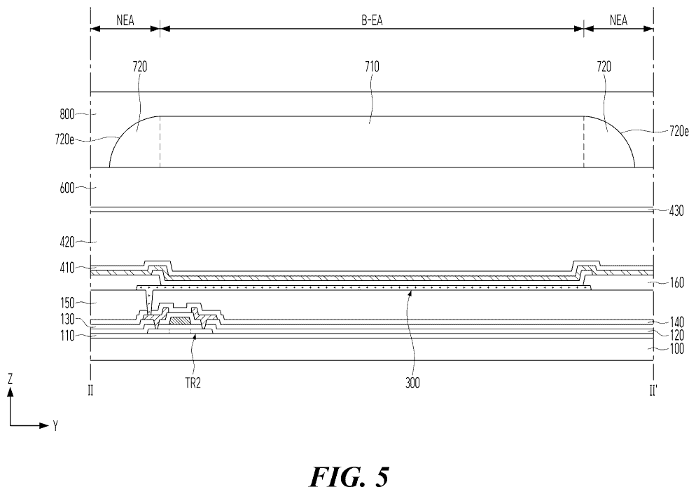

FIG. 1 is a view schematically showing a display apparatus according to an embodiment of the present disclosure. FIG. 2 is a view showing a circuit of a pixel area in the display apparatus according to the embodiment of the present disclosure. FIG. 3 is an enlarged view of K1 region in FIG. 1. FIG. 4 is a view taken along I-I′ of FIG. 3. FIG. 5 is a view taken along II-II′ of FIG. 3.

Referring to FIGS. 1 to 5, the display apparatus according to the embodiment of the present disclosure can include a display panel DP. The display panel DP can generate an image provided to a user. For example, pixel areas PA can be disposed in the display panel DP. Various signals can be provided in each pixel area PA through signal wirings GL, DL and PL. For example, the signal wirings GL, DL and PL can include gate lines GL applying a gate signal, data lines DL applying a data signal, and power voltage supply lines PL supplying a power voltage.

The gate lines GL can be electrically connected to a gate driver GD. The data lines DL can be electrically connected to a data driver DD. The gate driver GD and the data driver DD can be controlled by a timing controller TC. For example, the gate driver GD can receive clock signals, reset signals and a start signal from the timing controller TC, and the data driver DD can receive digital video data and a source timing signal from the timing controller TC. The power voltage supply lines PL can be electrically connected to a power unit PU.

The display panel DP can include an active area AA in which the pixel areas PA are disposed, and a bezel area BZ being disposed outside the active area AA. The bezel area BZ can be disposed outside the pixel areas PA. For example, the active area AA can be surrounded by the bezel area BZ. The gate driver GD, the data driver DD, the timing controller TC and the power unit PU can be disposed outside the active area AA. For example, each of the signal wirings GL, DL and PL can include a region disposed on the bezel area BZ.

At least one of the gate driver GD, the data driver DD, the timing controller TC and the power unit PU can be disposed on the bezel area BZ. For example, the display apparatus according to the embodiment of the present disclosure can be a GIP (Gate In Panel) type display apparatus in which the gate driver GD is formed on the bezel area BZ.

Each of the pixel areas PA emit light displaying a specific color according to the signal applied through the signal wirings GL, DL and PL. For example, a driving circuit DC electrically connected to a light-emitting device 300 can be disposed in each pixel area PA. The driving circuit DC of each pixel area PA can control the light-emitting device 300 of the corresponding pixel area PA according to signals applied to the signal wirings GL, DL and PL. For example, the driving circuit DC of each pixel area PA can supply a driving current corresponding to the data signal to the light-emitting device 300 of the corresponding pixel area PA according to the gate signal. The driving current supplied by the driving circuit DC of each pixel area PA can be maintained for one frame. For example, the driving circuit DC of each pixel area PA can include a first thin film transistor TR1, a second thin film transistor TR2 and a storage capacitor Cst.

The first thin film transistor TR1 of each pixel area PA can transmit the data signal to the second thin film transistor TR2 of the corresponding pixel area PA according to the gate signal. For example, the first thin film transistor TR1 of each pixel area PA can function as a switching thin film transistor. The first thin film transistor TR1 of each pixel area PA can include a first semiconductor pattern, a first gate electrode, a first drain electrode and a first source electrode. For example, the first gate electrode of each pixel area PA can be electrically connected to the corresponding gate line GL, and the first drain electrode of each pixel area PA can be electrically connected to the corresponding date line DL.

The first semiconductor pattern can include a semiconductor material. For example, the first semiconductor pattern can include Low-Temperature Poly-Si (LTPS) or an oxide semiconductor, such as IGZO. The first semiconductor pattern can include a first drain region, a first channel region and a first source region. The first channel region can be disposed between the first drain region and the first source region. The first drain region and the first source region can have a resistance smaller than the first channel region. For example, the first drain region and the first source region can include a conductive region of an oxide semiconductor. The first channel region can be a region of an oxide semiconductor, which is not conductorized.

The first gate electrode can be disposed on a portion of the first semiconductor pattern. For example, the first gate electrode can overlap the first channel region of the first semiconductor pattern. The first drain region and the first source region of the first semiconductor pattern can be disposed outside the first gate electrode. The first gate electrode can include a conductive material. For example, the first gate electrode can include a metal, such as aluminum (Al), chrome (Cr), copper (Cu), molybdenum (Mo), titanium (Ti) and tungsten (W). The first gate electrode can be spaced apart from the first semiconductor pattern. The first gate electrode can be insulated from the first semiconductor pattern. For example, the first drain region of the first semiconductor pattern can be electrically connected to the first source region of the first semiconductor pattern according to a signal applied to the first gate electrode.

The first drain electrode can include a conductive material. For example, the first drain electrode can include a metal, such as aluminum (Al), chrome (Cr), copper (Cu), molybdenum (Mo), titanium (Ti) and tungsten (W). The first drain electrode can include a different material from the first gate electrode. For example, the first drain electrode can be disposed on a different layer from the first gate electrode. The first drain electrode can be electrically connected to the first drain region of the first semiconductor pattern. The first drain electrode can be insulated from the first gate electrode.

The first source electrode can include a conductive material. For example, the first source electrode can include a metal, such as aluminum (Al), chrome (Cr), copper (Cu), molybdenum (Mo), titanium (Ti) and tungsten (W). The first source electrode can include a different material from the first gate electrode. The first source electrode can be disposed on a different layer from the first gate electrode. For example, the first source electrode can be disposed on a same layer as the first drain electrode. The first source electrode can include a same material as the first drain electrode. The first source electrode can be formed by a same process as the first drain electrode. For example, the first source electrode can be formed simultaneously with the first drain electrode. The first source electrode can be electrically connected to the first source region of the first semiconductor pattern. The first source electrode can be insulated from the first gate electrode. The first source electrode can be spaced apart from the first drain electrode.

The second thin film transistor TR2 of each pixel area PA can generate the driving current corresponding to the data signal. For example, the second thin film transistor TR2 of each pixel area PA can function as a driving thin film transistor. The second thin film transistor TR2 of each pixel area PA can include a second semiconductor pattern 221, a second gate electrode 223, a second drain electrode 225 and a second source electrode 227. For example, the second gate electrode 223 of each pixel area PA can be electrically connected to the first source electrode of the corresponding pixel area PA, and the second drain electrode 225 of each pixel area PA can be electrically connected to the corresponding power voltage supply line PL.

The second semiconductor pattern 221 can include a semiconductor material. For example, the second semiconductor pattern 221 can include Low-Temperature Poly-Si (LTPS) or an oxide semiconductor, such as IGZO. The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second semiconductor pattern 221 can include a second drain region, a second channel region and a second source region. The second channel region can be disposed between the second drain region and the second source region. The second drain region and the second source region can have a resistance smaller than the second channel region. For example, the second drain region and the second source region can include a conductive region of an oxide semiconductor. The second channel region can be a region of an oxide semiconductor, which is not conductorized.

The second gate electrode 223 can be disposed on a portion of the second semiconductor pattern 221. For example, the second gate electrode 223 can overlap the second channel region of the second semiconductor pattern 221. The second drain region and the second source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the second channel region of the second semiconductor pattern 221 can have an electrical conductivity corresponding to a voltage applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. For example, the second drain electrode 225 can be disposed on a different layer from the second gate electrode 223. The second drain electrode 225 can be electrically connected to the second drain region of the second semiconductor pattern 221. The second drain electrode 225 can be insulated from the second gate electrode 223.

The second drain electrode 225 can be disposed a same layer as the first drain electrode. The second drain electrode 225 can include a same material as the first drain electrode. The second drain electrode 225 can be formed by a same process as the first drain electrode. For example, the second drain electrode 225 can be formed simultaneously with the first drain electrode.

The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. The second source electrode 227 can be disposed on a different layer from the second gate electrode 223. For example, the second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be electrically connected to the second source region of the second semiconductor pattern 221. The second source electrode 227 can be insulated from the second gate electrode 223. The second source electrode 227 can be spaced apart from the second drain electrode 225.

The storage capacitor Cst of each pixel area PA can maintain a voltage applied to the second gate electrode 223 of the corresponding pixel area PA for one frame. For example, the storage capacitor Cst of each pixel area PA can be electrically connected to the second gate electrode 223 and the second source electrode 227 of the corresponding pixel area PA. The storage capacitor Cst of each pixel area PA can have a stacked structure of capacitor electrodes. For example, the storage capacitor Cst of each pixel area PA can include a first capacitor electrode electrically connected to the second gate electrode 233 of the corresponding pixel area PA, and a second capacitor electrode electrically connected to the second source electrode 227 of the corresponding pixel area PA.

The first capacitor electrode and the second capacitor electrode of each pixel area PA can be formed by using a process of forming the first thin film transistor TR1 and the second thin film transistor TR2 in the corresponding pixel area PA. For example, the first capacitor electrode of each pixel area PA can be disposed on a same layer as the second gate electrode 223 of the corresponding pixel area PA, and the second capacitor electrode of each pixel area PA can be disposed on a same layer as the second source electrode 227 of the corresponding pixel area PA. The first capacitor electrode of each pixel area PA can include a same material as the second gate electrode 223 of the corresponding pixel area PA, and the second capacitor electrode of each pixel aera PA can include a same material as the second source electrode 227 of the corresponding pixel area PA. The first capacitor electrode of each pixel area PA can be formed by a same process as the second gate electrode 223 of the corresponding pixel area PA, and the second capacitor electrode of each pixel area PA can be formed by a same process as the second source electrode 227 of the corresponding pixel area PA. For example, the first capacitor electrode of each pixel area PA can be formed simultaneously with the second gate electrode 223 of the corresponding pixel area PA, and the second capacitor electrode of each pixel area PA can be formed simultaneously with the second source electrode 227 of the corresponding pixel area PA. Thus, in the display apparatus according to the embodiment of the present disclosure, a process of forming the driving circuit DC in each pixel area PA can be simplified.

The light-emitting device 300 and the driving circuit DC of each pixel area PA can be supported by a device substrate 100. For example, the light-emitting device 300 and the driving circuit DC of each pixel area PA can be disposed on the device substrate 100. The device substrate 100 can include an insulating material. For example, the device substrate 100 can include glass or plastic.

A plurality of insulating layers 110, 120, 130, 140, 150 and 160 for preventing unnecessary electrical connection can be disposed on the device substrate 100. For example, a buffer insulating layer 110, a gate insulating layer 120, an interlayer insulating layer 130, a device passivation layer 140, a planarization layer 150 and a bank insulating layer 160 can be disposed on the device substrate 100.

The buffer insulating layer 110 can be disposed on the device substrate 100. The buffer insulating layer 110 can prevent the pollution due to the device substrate 100 in a process of forming the driving circuit DC of each pixel area PA. For example, the buffer insulating layer 110 can extend along an upper surface of the device substrate 100 toward the driving circuit DC of each pixel area PA. The driving circuit DC of each pixel area PA can be disposed on the buffer insulating layer 110. The buffer insulating layer 110 can include an insulating material. For example, the buffer insulating layer 110 can include an inorganic insulating material, such as silicon oxide (SiOx) and silicon nitride (SiNx). The buffer insulating layer 110 can have a multi-layer structure. For example, the buffer insulating layer 110 can have a structure in which an inorganic insulating layer made of silicon oxide (SiOx) and an inorganic insulating layer made of silicon nitride (SiNx) are stacked.

The gate insulating layer 120 can be disposed on the buffer insulating layer 110. The first gate electrode of each pixel area PA can be insulated from the first semiconductor pattern of the corresponding pixel area PA by the gate insulating layer 120. The second gate electrode 223 of each pixel area PA can be insulated from the second semiconductor pattern 221 of the corresponding pixel area PA by the gate insulating layer 120. For example, the gate insulating layer 120 can cover the first semiconductor pattern and the second semiconductor pattern 221 of each pixel area PA. The first gate electrode and the second gate electrode 223 of each pixel area PA can be disposed on the gate insulating layer 120. The gate insulating layer 120 can include an insulating material. For example, the gate insulating layer 120 can include an inorganic insulating material, such as silicon oxide (SiOx) and silicon nitride (SiNx).

The interlayer insulating layer 130 can be disposed on the gate insulating layer 120. The first drain electrode and the first source electrode of each pixel area PA can be insulated from the first gate electrode of the corresponding pixel area PA by the interlayer insulating layer 130. The second drain electrode 225 and the second source electrode 227 of each pixel area PA can be insulated from the second gate electrode 223 of the corresponding pixel area PA by the interlayer insulating layer 130. For example, the interlayer insulating layer 130 can cover the first gate electrode and the second gate electrode 223 of each pixel area PA. The first drain electrode, the first source electrode, the second drain electrode 225 and the second source electrode 227 of each pixel area PA can be disposed on the interlayer insulating layer 130. The interlayer insulating layer 130 can include an insulating material. For example, the interlayer insulating layer 130 can include an inorganic insulating material.

The device passivation layer 140 can be disposed on the interlayer insulating layer 130. The device passivation layer 140 can prevent the damage of the driving circuit DC in each pixel area PA due to external impact and moisture. For example, the first drain electrode, the first source electrode, the second drain electrode 225 and the second source electrode 227 of each pixel area PA can be covered by the device passivation layer 140. The device passivation layer 140 can extend beyond the driving circuit DC in each pixel area PA. The device passivation layer 140 can include an insulating material. For example, the device passivation layer 140 can be a linear insulating layer made of an inorganic insulating material.

The planarization layer 150 can be disposed on the device passivation layer 140. The planarization layer 150 can remove a thickness difference due to the driving circuit DC of each pixel area PA. For example, an upper surface of the planarization layer 150 opposite to the device substrate 100 can be a flat. The upper surface of the planarization layer 150 can be parallel to the upper surface of the device substrate 100. The planarization layer 150 can include an insulating material. The planarization layer 150 can include a different material from the device passivation layer 140. The planarization layer 150 can include a material having a relatively high fluidity. For example, the planarization layer 150 can include an organic insulating material.

The light-emitting device 300 of each pixel area PA can be disposed on the planarization layer 150. The light-emitting device 300 of each pixel area PA can emit light displaying a specific color. For example, the light-emitting device 300 of each pixel area PA can include a first electrode 310, a light-emitting layer 320 and a second electrode 330, which are sequentially stacked on the planarization layer 150 of the corresponding pixel area PA.

The first electrode 310 can include a conductive material. The first electrode 310 can include a material having a relatively high reflectance. For example, the first electrode 310 can include a metal, such as aluminum (Al) or silver (Ag). The first electrode 310 can have a multi-layer structure. For example, the first electrode 310 can have a structure in which a reflective electrode made of a metal is disposed between transparent electrodes made of a transparent conductive material, such as ITO and IZO.

The light-emitting layer 320 can generate light having luminance corresponding to a voltage difference between the first electrode 310 and the second electrode 330. For example, the light-emitting layer 320 can include at least one emission material layer (EML). The emission material layer can include an organic emission material, an inorganic emission material, or a hybrid emission material. For example, the display apparatus according to the embodiment of the present disclosure can be an organic light-emitting display apparatus including an organic emission material.

The light-emitting layer 320 can have a multi-layer structure. For example, the light-emitting layer 320 can include at least one of a hole injection layer (HIL), a hole transport layer (HTL), an electron transport layer (ETL) and an electron injection layer (EIL). Thus, in the display apparatus according to the embodiment of the present disclosure, the emission efficiency of the light-emitting layer 320 can be improved.

The second electrode 330 can include a conductive material. The second electrode 330 can include a different material from the first electrode 310. A transmittance of the second electrode 330 can be greater than a transmittance of the first electrode 310. For example, the second electrode 330 can be a transparent electrode made of a transparent conductive material, such as ITO and IZO. Thus, in the display apparatus according to the embodiment of the present disclosure, the light generated by the light-emitting layer 320 can be emitted outside through the second electrode 330. The second electrode 330 can have a work-function smaller than the first electrode 310. For example, the first electrode 310 can function as anode electrode, and the second electrode 330 can function as cathode electrode.

The bank insulating layer 160 can be disposed on the planarization layer 150. The first electrode 310 of each pixel area PA can be insulated from the first electrode 310 of adjacent pixel area PA by the bank insulating layer 160. For example, an edge of the first electrode 310 in each pixel area PA can be covered by the bank insulating layer 160. The first electrode 310 of each pixel area PA can be partially exposed by the bank insulating layer 160. For example, the bank insulating layer 160 can define an emission area R-EA, G-EA and B-EA in each pixel area PA. The light-emitting layer 320 and the second electrode 330 of each pixel area PA can be stacked on the corresponding first electrode 310 within the emission area R-EA, G-EA and B-EA defined by the bank insulating layer 160. For example, the light-emitting layer 320 can be in direct contact with the first electrode 310 and the second electrode 330 on the emission area R-EA, G-EA and B-EA of each pixel area PA. The bank insulating layer 160 can include an insulating material. For example, the bank insulating layer 160 can be an organic insulating material. The bank insulating layer 160 can include a different material from the planarization layer 150.

The first electrode 310 of each pixel area PA can be electrically connected to the driving circuit DC of the corresponding pixel area PA. For example, the first electrode 310 of each pixel area PA can be in direct contact with the second source electrode 227 of the corresponding pixel area PA by penetrating the device passivation layer 140 and the planarization layer 150. The device passivation layer 140 and the planarization layer 150 can include pixel contact holes partially exposing the second source electrode 227 of each pixel area PA. The first electrode 310 of each pixel area PA can be connected to the second source electrode 227 of the corresponding pixel area PA through one of the pixel contact holes. The pixel contact holes can overlap the bank insulating layer 160. Thus, in the display apparatus according to the embodiment of the present disclosure, the change in the location of the first electrode in the emission area R-EA, G-EA and B-EA of each pixel area PA can be minimized. For example, a portion of the first electrode 310 overlapping with the emission area R-EA, G-EA and B-EA of each pixel area PA can be in direct contact with the upper surface of the planarization layer 150. Therefore, in the display apparatus according to the embodiment of the present disclosure, luminance deviation according to the generating location of the light emitted from the emission area R-EA, G-EA and B-EA of each pixel area PA can be prevented.

A voltage applied to the second electrode 330 of each pixel area PA can be a same as a voltage applied to the second electrode 330 of adjacent pixel area PA. For example, the second electrode 330 of each pixel area PA can be electrically connected to the second electrode 330 of adjacent pixel area PA. The second electrode 330 of each pixel area PA can include a same material as the second electrode 330 of adjacent pixel area PA. The second electrode 330 of each pixel area PA can be formed by a same process as the second electrode of adjacent pixel area PA. For example, the second electrode 330 of each pixel area PA can be formed simultaneously with the second electrode 330 of adjacent pixel area PA. The second electrode 330 of each pixel area PA can extend beyond the corresponding pixel area PA. For example, the second electrode 330 of each pixel area PA can be in direct contact with the second electrode 330 of adjacent pixel area PA on the bank insulating layer 160. Thus, in the display apparatus according to the embodiment of the present disclosure, a process of forming the second electrode 330 in each pixel area PA can be simplified. And, in the display apparatus according to the embodiment of the present disclosure, the luminance of the light generated by the light-emitting layer 320 of each pixel area PA can be adjusted by the data signal applied to the driving circuit DC of the corresponding pixel area PA.

The image realized by light emitted from the light-emitting device 300 of each pixel area PA can include various colors. The light emitted from the light-emitting device 300 of each pixel area PA can display a different color from the light emitted from the light-emitting device 300 of adjacent pixel area PA in a first direction X, as shown in FIGS. 3 to 5. For example, the emission area R-EA, G-EA and B-EA of each pixel area PA can be one of a red emission area R-EA in which red light displaying red color is emitted, a green emission area G-EA in which green light displaying green color is emitted, and a blue emission area B-EA in which blue light displaying blue color is emitted, and the red emission areas R-EA, the green emission areas G-EA and the blue emission areas B-EA can be repeated in the first direction X. The light-emitting layer 320 of each pixel area PA can be spaced apart from the light-emitting layer 320 of adjacent pixel area PA in the first direction X. For example, the light-emitting layer 320 of each pixel area PA can be one of a red light-emitting layer generating the red light, a green light-emitting layer generating the green light and a blue light-emitting layer generating the blue light, and the pixel area PA including the red light-emitting layer, the pixel area PA including the green light-emitting layer and the pixel area PA including the blue light-emitting layer can be repeated in the first direction X. The light-emitting layer 320 of each pixel area PA can include a different material from the light-emitting layer 320 of adjacent pixel area PA in the first direction X. The light-emitting layer 320 of each pixel area PA can have a stacked structure different from the light-emitting layer 320 of adjacent pixel area PA in the first direction X. For example, the light-emitting layer 320 of each pixel area PA can be spaced apart from the light-emitting layer 320 of adjacent pixel area PA in the first direction X on the bank insulating layer 160.

The pixel areas PA can be disposed side by side in a first direction X and a second direction Y perpendicular to the first direction X. For example, the pixel areas PA can be arranged in a matrix form. The light emitted from the light-emitting device 300 of each pixel area PA can display a same color as the light emitted from the light-emitting device 300 of adjacent pixel area PA in the second direction Y. For example, the light-emitting layer 320 of each pixel area PA can include a same material as the light-emitting layer 320 of adjacent pixel area PA in the second direction Y. The light-emitting layer 320 of each pixel area PA can be spaced apart from the light-emitting layer 320 of adjacent pixel area PA. For example, the light-emitting layer 320 of each pixel area PA can be spaced apart from the light-emitting layer 320 of adjacent pixel area PA in the second direction Y on the bank insulating layer 160.

As shown in FIG. 3, a plane of the emission area R-EA, G-EA and B-EA defined in each pixel area PA can have a same shape as a plane of the emission area R-EA, G-EA and B-EA defined in adjacent pixel area PA. For example, the plane of the emission area R-EA, G-EA and B-EA defined in each pixel area PA can have a bar shape extending in the second direction Y. A length of the emission area R-EA, G-EA and B-EA of each pixel area PA in the first direction X can be smaller than a length of the emission area R-EA, G-EA and B-EA of the corresponding pixel area PA in the second direction Y. The plane of the emission area R-EA, G-EA and B-EA defined in each pixel area PA can be a same area as the plane of the emission area R-EA, G-EA and B-EA defined in adjacent pixel area PA.

As shown in FIG. 4, an encapsulation structure 400 can be disposed on the light-emitting device 300 of each pixel area PA. The encapsulation structure 400 can prevent the damage of the light-emitting device 300 in each pixel area PA due to the external impact and moisture. The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a different material from the first encapsulating layer 410 and the third encapsulating layer 430. For example, the first encapsulating layer 410 and the third encapsulating layer 430 can include an inorganic insulating material, and the second encapsulating layer 420 can include an organic insulating material. Thus, in the display apparatus according to the embodiment of the present disclosure, the damage of the light-emitting device 300 in each pixel area PA due to the external impact and moisture can be effectively prevented. A thickness difference due to the light-emitting device 300 of each pixel area PA can be removed by the second encapsulating layer 420. The second encapsulating layer 420 can have a greater thickness than the first encapsulating layer 410 and the third encapsulating layer 430. For example, an upper surface of the encapsulation structure 400 opposite to the device substrate 100 can be a flat surface.

A barrier structure 500 can be disposed on the encapsulation structure 400. The barrier structure 500 can be spaced apart from the emission area R-EA, G-EA and B-EA of each pixel area PA. For example, the barrier structure 500 can be disposed between adjacent emission areas R-EA, G-EA and B-EA. A region disposed between adjacent emission areas R-EA, G-EA and B-EA can be defined as a non-emission area NEA. For example, the barrier structure 500 can be disposed within the non-emission area NEA. The barrier structure 500 can have a stacked structure of barrier patterns 510 and 520. For example, the barrier structure 500 can include a first barrier pattern 510 and a second barrier pattern 520, which are stacked on the non-emission area NEA. The first barrier pattern 510 and the second barrier pattern 520 can overlap the bank insulating layer 160.

The first barrier pattern 510 can be disposed close to the upper surface of the encapsulation structure 400. For example, the first barrier pattern 510 can be in direct contact with the third encapsulating layer 430 of the non-emission area NEA. The second barrier pattern 520 can be disposed on the first barrier pattern 510. The second barrier pattern 520 can be spaced apart from the first barrier pattern 510. For example, the second barrier pattern 520 can be disposed on an optical insulating layer 600 covering the first barrier pattern 510. The optical insulating layer 600 can be disposed on the encapsulation structure 400. The optical insulating layer 600 can overlap the emission areas R-EA, G-EA and B-EA and the non-emission area NEA. The optical insulating layer 600 can include an insulating material. The optical insulating layer 600 can include a transparent material. For example, the optical insulating layer 600 can include an inorganic insulating material and/or an organic insulating material. The optical distance of the light emitted from the light-emitting device 300 of each pixel area PA can be sufficiently secured by the optical insulating layer 600. An upper surface of the optical insulating layer 600 opposite to the encapsulation structure 400 can be flat. For example, the upper surface of the optical insulating layer 600 can be parallel to the upper surface of the encapsulation structure 400. The second barrier pattern 520 can be in direct contact with the optical insulating layer 600 of the non-emission area NEA.

The second barrier pattern 520 can overlap the first barrier pattern 510. The first barrier pattern 510 and second barrier pattern 520 can include a material blocking light. For example, the first barrier pattern 510 and the second barrier pattern 520 can include a black dye, such as carbon black. Thus, in the display apparatus according to the embodiment of the present disclosure, the traveling direction of the light emitted from each emission area R-EA, G-EA and B-EA can be limited by the first barrier pattern 510 and the second barrier pattern 520. The second barrier pattern 520 can include a same material as the first barrier pattern 510. The second barrier pattern 520 can be formed to have a same size as the first barrier pattern 510. For example, the second barrier pattern 520 can have a plane of a same shape as the first barrier pattern 510.

The first barrier pattern 510 and the second barrier pattern 520 can extend in a direction. For example, the first barrier pattern 510 and the second barrier pattern 520 can extend in the second direction Y. Thus, in the display apparatus according to the embodiment of the present disclosure, the light emitted from each emission area R-EA, G-EA and B-EA in the first direction X can be blocked by the first barrier pattern 510 and the second barrier pattern 520. That is, in the display apparatus according to the embodiment of the present disclosure, the viewing angle in the first direction X can be limited by the first barrier pattern 510 and the second barrier pattern 520. Therefore, in the display apparatus according to the embodiment of the present disclosure, an image by the light emitted from the emission areas R-EA, G-EA and B-EA can't be recognized by people disposed adjacent to the user in the first direction X.

Pixel lenses 700 can be disposed on the optical insulating layer 600. Each of the pixel lenses 700 can overlap the emission area R-EA, G-EA and B-EA of one of the pixel areas PA. The light emitted from the light-emitting device 400 of each pixel area PA can be focused by one of the pixel lenses 700. For example, a surface of the pixel lens 700 opposite to the optical insulating layer 600 on each pixel area PA can have a convex shape. As shown in FIGS. 3 to 5, the pixel lens 700 of each pixel area PA can have a greater size than the emission area R-EA, G-EA and B-EA of the corresponding pixel area PA. For example, a side of each pixel lens 700 extending in the second direction Y can overlap the second barrier pattern 520. Thus, in the display apparatus according to the embodiment of the present disclosure, the light that is not blocked by the barrier structure 500 can be provided to the user through the pixel lenses 700. That is, in the display apparatus according to the embodiment of the present disclosure, the loss of the light between the second barrier pattern 520 and the pixel lenses 700 can be minimized. Therefore, in the display apparatus according to the embodiment of the present disclosure, the light extraction efficiency can be improved.

As shown in FIG. 3, the pixel lens 700 of each pixel area PA can extend in the second direction Y. For example, a plane of the pixel lens 700 disposed on each pixel area PA can have a greater size than a plane of the emission area R-EA, G-EA and B-EA defined in the corresponding pixel area PA. For example, the pixel lens 700 of each pixel area PA can include a first lens region 710 disposed on the emission area R-EA, G-EA and B-EA of the corresponding pixel area PA and a second lens region 720 disposed side by side with the first lens region 710 in the second direction Y.

As shown in FIGS. 3 to 5, the first lens region 710 of each pixel area PA can overlap the emission area R-EA, G-EA and B-EA of the corresponding pixel area PA. A plane of the first lens region 710 disposed on each pixel area PA can have a shape corresponding to a plane of the emission area R-EA, G-EA and B-EA defined in the corresponding pixel area PA. For example, the first lens region 710 of each pixel area PA can have a bar shape extending in the second direction Y. A cross-section of the first lens region 710 on each pixel in the first direction X can have a curved shape. A cross-section of the first lens region 710 on each pixel area PA in the second direction Y can have a constant thickness.

A length of the first lens region 710 on each pixel area in the first direction X have a greater than the length of the emission area R-EA, G-EA and B-EA defined in the corresponding pixel area PA in the first direction X. For example, a side of the first lens region 710 on each pixel area PA extending in the second direction Y can overlap the second barrier pattern 520. The side of the first lens region 710 on each pixel area PA extending in the second direction Y can be parallel to a side of the emission area R-EA, G-EA and B-EA on the corresponding pixel area PA in the second direction Y. For example, a distance between the first lens region 710 and the emission area R-EA, G-EA and B-EA on each pixel area PA can be constant. A length of the first lens region 710 on each pixel area PA in the second direction Y can be a same as a length of the emission area R-EA, G-EA and B-EA defined in the corresponding pixel area PA in the second direction Y.

The second lens region 720 of each pixel area PA can include a same material as the first lens region 710 of the corresponding pixel area PA. The second lens region 720 of each pixel area PA can be in direct contact with the first lens region 710 of the corresponding pixel area PA. A refractive index of the second lens region 720 on each pixel area PA can be a same as a refractive index of the first lens region 710 on the corresponding pixel area PA. The second lens region 720 of each pixel area PA can be formed by a same process as the first lens region 710 of the corresponding pixel area PA. For example, the second lens region 720 of each pixel area PA can be formed simultaneously with the first lens region 710 of the corresponding pixel area PA. A boundary between the first lens region 710 and the second lens region 720 of each pixel area PA can't be recognized. Thus, in the display apparatus according to the embodiment of the present disclosure, the reflection and the refraction of the light at the boundary between the first lens region 710 and the second lens region 720 of each pixel area PA can be prevented. Therefore, in the display apparatus according to the embodiment of the present disclosure, the decrease in the light extraction efficiency due to the boundary between the first lens region 710 and the second lens region 720 of each pixel area PA can be prevented.

A plane of the second lens region 720 on each pixel area PA can have a shape extending from the first lens region 710 on the corresponding pixel area PA in the second direction Y. For example, the maximum length of the second lens region 720 on each pixel area PA in the first direction X can be a same as the length of the first lens region 710 on the corresponding pixel area PA in the first direction X. An end portion of the second lens region 720 on each pixel area PA toward the first direction X can overlap the second barrier pattern 520. An end portion 720e of the second lens region 720 on each pixel area PA toward the second direction Y can't overlap the second barrier pattern 520.

The second lens region 720 on each pixel area PA can be disposed outside the emission area R-EA, G-EA and B-EA defined in the corresponding pixel area PA. For example, the second lens region 720 of each pixel area PA can be disposed on the non-emission area NEA. The second lens region 720 of each pixel area PA can't overlap the emission area R-EA, G-EA and B-EA of the corresponding pixel area PA. For example, the second lens region 720 on each pixel area PA can be disposed side by side with the emission area R-EA, G-EA and B-EA defined in the corresponding pixel area PA in the second direction Y.

As shown in FIG. 3, the end portion 720e of the second lens region 720 on each pixel area PA toward the second direction Y can have a different shape from an end portion EAe of the emission area R-EA, G-EA and B-EA defined in the corresponding pixel area PA toward the second direction Y. For example, a plane of the end portion 720e of the second lens region 720 on each pixel area PA toward the second direction Y can be a curved shape having a larger curvature than a plane of the end portion EAe of the emission area R-EA, G-EA and B-EA defined in the corresponding pixel area PA toward the second direction Y.

A distance between the end portion 720e of the second lens region 720 and the end portion EAe of the emission area R-EA, G-EA and B-EA toward the second direction Y on each pixel area can be larger than a distance between the side of the first lens region 710 and the side of the emission area R-EA, G-EA and B-EA extending in the second direction Y on the corresponding pixel area PA. The end portion 720e of the second lens region 720 on each pixel area PA toward the second direction Y can have a curved shape. A thickness of the second lens region 720 on each pixel area PA can decrease as a distance from the emission area R-EA, G-EA and B-EA of the corresponding pixel area PA increases. The maximum thickness of the second lens region 720 on each pixel area PA can be a same as the maximum thickness of the first lens region 710 on the corresponding pixel area PA. For example, the second lens region 720 on each pixel area PA can have a same shape as a portion of a sphere whose diameter is the length of the first lens area 710 on the corresponding pixel area PA in the first direction X. Thus, in the display apparatus according to the embodiment of the present disclosure, the light emitted from the light-emitting device 300 of each pixel area PA toward the second lens region 720 of the corresponding pixel area PA can be focused toward the center of the corresponding pixel area PA. Therefore, in the display apparatus according to the embodiment of the present disclosure, the viewing angle in the first direction X can be limited by the first barrier pattern 510 and the second barrier pattern 520, and the frontal luminance of each pixel area PA can be increased by a plane shape of the second lens region 720 on the corresponding pixel area PA.

A plane of the pixel lens 700 on each pixel area PA can have a symmetrical shape with respect to the center portion of the emission area R-EA, G-EA and B-EA defined in the corresponding pixel area PA. Thus, in the display apparatus according to the embodiment of the present disclosure, the light can be uniformly focused by the pixel lens 700 of each pixel area PA. And, in the display apparatus according to the embodiment of the present disclosure, the light extraction efficiency can be improved by the second lens region 720 of each pixel area PA.

As shown in FIGS. 4 and 5, a lens passivation layer 800 can be disposed on the pixel lens 700 of each pixel area PA. The lens passivation layer 800 can prevent the damage of the pixel lenses 700 due to the external impact. For example, the surface of each pixel lens 700 that is opposite to the optical insulating layer 600 and having a convex shape can be completely covered by the lens passivation layer 800. The lens passivation layer 800 can overlap the emission area R-EA, G-EA and B-EA and the non-emission area NES of each pixel area PA. The lens passivation layer 800 can be in direct contact with the surface of each pixel lens 700 that is opposite to the optical insulating layer 600 and having a convex shape. A refractive index of the lens passivation layer 800 can be smaller than a refractive index of each pixel lens 700. Thus, in the display apparatus according to the embodiment of the present disclosure, the reflection of the light due to a difference in the refractive index can be prevented at a boundary between each pixel lens 700 and the lens passivation layer 800.

Table 1 shows the reflection characteristics of the comparative display apparatus (comparative example) in which the end portion 720e of the second lens area 720 on each pixel area PA toward the second direction Y has a same plane shape as the end portion EAe of the emission area R-EA, G-EA and B-EA on the corresponding pixel area PA toward the second direction Y, and the display apparatus (experimental example) according to the embodiment of the present disclose. Here, Specular means regular reflection, Diffuse means diffuse reflection, and Matrix Scatter means rainbow stains generated by the interference of refracted light and/or reflected light.

TABLE 1

| | Specular | Diffuse | Matrix Scatter |
|---|---|---|---|
| Comparative example | 4.01% | 0.52% | 0.013% |
| Experimental example | 4.57% | 0.20% | 0.005% |

Referring to Table 1, the display apparatus (experimental example) according to the embodiment of the present disclosure can have significantly lower the diffuse reflection and the rainbow stains than the comparative display apparatus (comparative Example). That is, in the display apparatus (experimental example) according to the embodiment of the present disclosure, the diffuse reflection and the rainbow stains can be significantly reduced by the plane shape of the end portion 720e of the second lens region 720 on each pixel area PA toward the second direction Y. Thus, in the display apparatus (experimental example) according to the embodiment of the present disclosure, the color mixing due to the diffuse reflection and the decrease in the quality of the image due to the rainbow stains can be significantly reduced. Therefore, in the display apparatus (experimental example) according to the embodiment of the present disclosure, the quality of the image recognized by the user can be improved.

Accordingly, the display apparatus according to the embodiment of the present disclosure can include the light-emitting device 300, the encapsulation structure 400, the barrier structure 500, the optical insulating layer 600, the pixel lens 700 and the lens passivation layer 800 in each pixel area PA, wherein the first barrier pattern 510 and the second barrier pattern 520 of the barrier structure 500 overlapping with the non-emission area NEA can extend in the second direction Y, wherein the pixel lens 700 of each pixel area PA can include the first lens region 710 overlapping with the emission area R-EA, G-EA and B-EA on the corresponding pixel area PA and the second lens region 720 extending from the first lens region 710 in the second direction Y, and wherein the plane of the end portion 720e of the second lens region 720 on each pixel area PA that does not overlap the barrier structure 500 can have a greater curvature than the plane of the end portion EAe of the emission area R-EA, G-EA and B-EA on the corresponding pixel area PA toward the second direction Y. Thus, in the display apparatus according to the embodiment of the present disclosure, the light emitted from the light-emitting device 300 of each pixel area PA toward the non-emission area NEA adjacent in the second direction Y can be focused toward the center of the corresponding pixel area PA by the second lens region 720 of the corresponding pixel area PA. And, in the display apparatus according to the embodiment of the present disclosure, the color mixing due to the diffuse reflection and the rainbow stains can be reduced. Therefore, in the display apparatus according to the embodiment of the present disclosure, the frontal luminance of each pixel area PA can be increased by the second lens region 720 of the corresponding pixel area PA, and the decrease in the quality of the image due to the color mixing and the rainbow stains can be reduced. That is, in the display apparatus according to the embodiment of the present disclosure, the light extraction efficiency and the quality of the image can be improved.

The display apparatus according to the embodiment of the present disclosure is described that the driving circuit DC of each pixel area PA can consist of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor capable of initializing the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor material. The third gate electrode of each pixel area PA can be electrically connected to the corresponding gate line GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in configuring each driving circuit DC can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

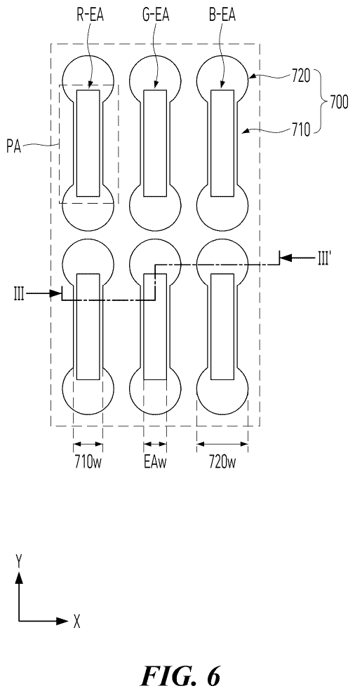

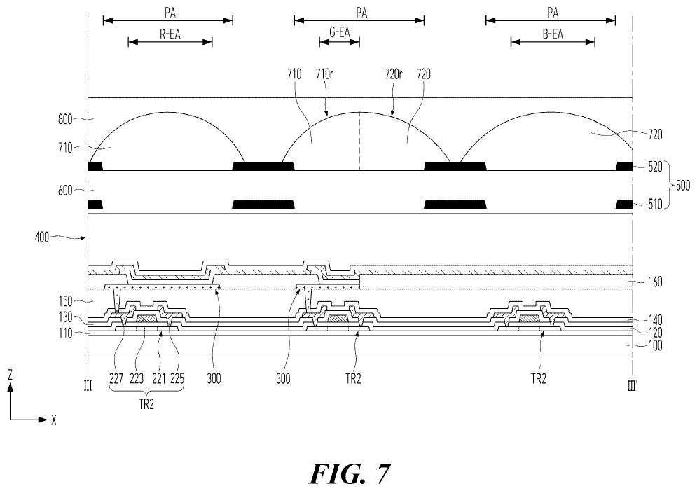

The display apparatus according to the embodiment of the present disclosure is described that the maximum length of the second lens region 720 on each pixel area PA in the first direction X can be a same as the length of the first lens region 710 on the corresponding pixel area PA in the first direction X. However, in the display apparatus according to another embodiment of the present disclosure, the maximum length of the second lens region 720 on each pixel area PA in the first direction X can be a greater than the length of the first lens region 710 on the corresponding pixel area PA in the first direction X. For example, in the display apparatus according to the embodiment of the present disclosure, the plane shape of the second lens region 720 on each pixel area PA can be close to a circle, as shown in FIGS. 6 and 7. A portion of the second lens region 720 on each pixel area PA overlapping with the second barrier pattern 520 can have a curved shape. For example, a portion of the second lens region 720 on each pixel area PA overlapping with the second barrier pattern 520 can have a greater area than a portion of the first lens region 710 on the corresponding pixel area PA overlapping with the second barrier pattern 520. The maximum thickness of the cross-section of the second lens region 720 on each pixel area PA in the first direction X can be a same as the maximum thickness of the cross-section of the first lens region 710 on the corresponding pixel area PA in the first direction X. For example, a convex surface 720r of the second lens region 720 on each pixel area PA can have a different curvature from a convex surface 710r of the first lens region 710 on the corresponding pixel area PA.

Table 2 shows the viewing angle having 10% luminance, the frontal luminance, the luminance of a first setting area, the luminance of a second setting area and the luminance of a third setting area according to the length of the second lens region 720 on each pixel area PA in the first direction X with respect to the length of the first lens region 710 on the corresponding pixel area PA in the first direction X. Here, the viewing angle having 10% luminance means an angle at a point where the luminance is 10% compared to the front. And, the first setting area means an area within +4° in the first direction X and +10° in the second direction Y based on the front, the second setting area means an area within +20° in the first direction X and +40° in the second direction Y based on the front, and the third setting area means an area within +20° in the first direction X and +50° in the second direction Y based on the front.

TABLE 2

| | the length of the second | | | |
|---|---|---|---|---|
| | lens region with respect to the | | | |
| | length of the first lens region | | | |
| | 100% | 120% | 140% | 160% |
| viewing angle having 10% luminance | 28° | 27° | 27° | 27° |
| luminance of front | 1200 | 1218 | 1220 | 1203 |
| luminance of first setting area | 1107 | 1125 | 1118 | 1078 |
| luminance of second setting area | 443 | 452 | 447 | 438 |
| luminance of third setting area | 304 | 310 | 313 | 314 |

Referring to Table 2, in the display apparatus according to the embodiment of the present disclosure, when the length of the second lens region 720 on each pixel area PA in the first direction X with respect to the length of the first lens region 710 on the corresponding pixel area PA in the first direction X is 100% to 160%, the image recognized by the user can have high overall luminance without changing the viewing angle. Further, in the display apparatus according to the embodiment of the present disclosure, when the length of the second lens region 720 on each pixel area PA in the first direction X with respect to the length of the first lens region 710 on the corresponding pixel area PA in the first direction X is 120% to 140%, the luminance of the front, the first setting area, the second setting area and the third setting area can be maximized. That is, in the display apparatus according to the embodiment of the present disclosure, the length of the second lens region 720 on each pixel area PA in the first direction X with respect to the length of the first lens region 710 on the corresponding pixel area PA in the first direction X can be 100% to 160%, preferably 120% to 140%. Thus, in the display apparatus according to the embodiment of the present disclosure, the light extraction efficiency can be effectively improved.

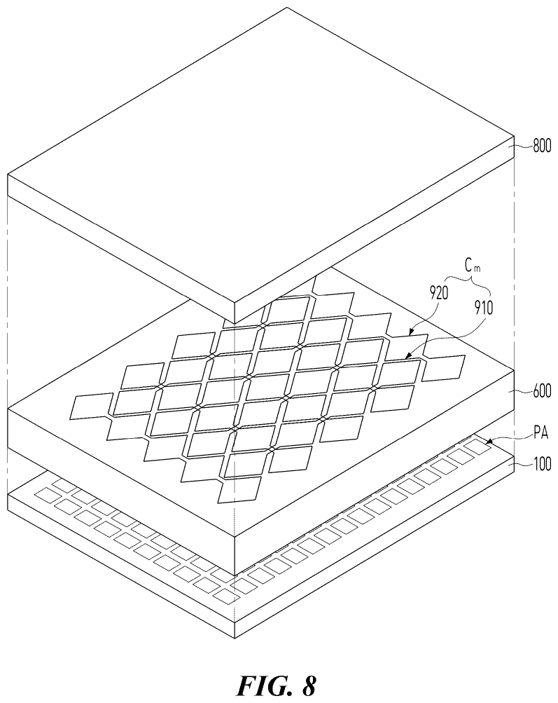

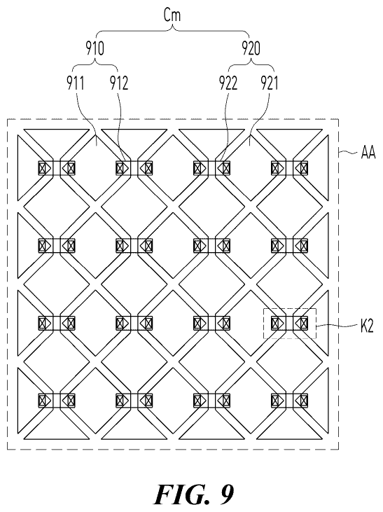

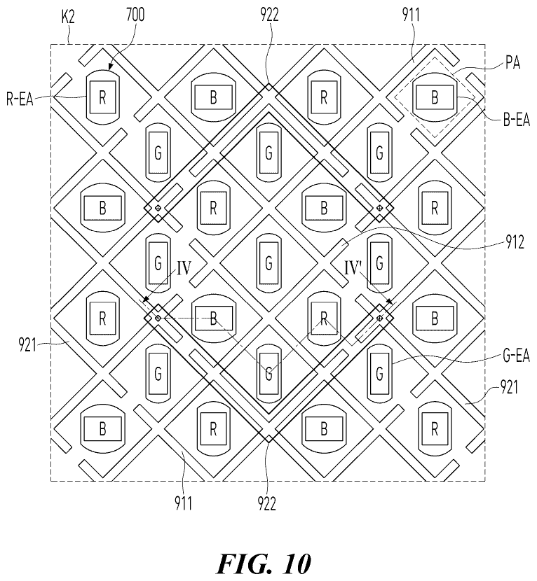

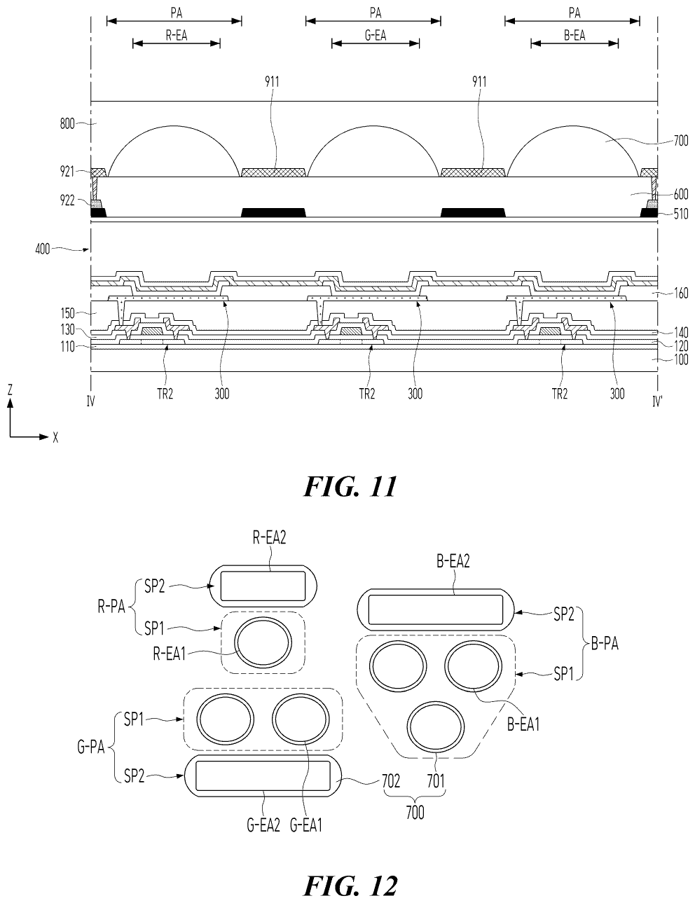

The display apparatus according to the embodiment of the present disclosure is described that the second barrier pattern 520 can include a same material as the first barrier pattern 510. However, in the display apparatus according to another embodiment of the present disclosure, the second barrier pattern 520 can include a different material from the first barrier pattern 510. For example, in the display apparatus according to another embodiment of the present disclosure, a touch sensor Cm can be disposed between the encapsulation structure 400 and the lens passivation layer 800, as shown in FIGS. 8 to 11. The touch sensor Cm can sense a touch of the user and/or a tool. For example, the touch sensor Cm can detect presence or absence of the touch and the touch position of the user and/or the tool using the change of a mutual capacitance.

The touch sensor Cm can include driving touch lines 910 in which a touch driving signal is applied, and sensing touch lines 920 in which a touch sensing signal is applied. Each of the driving touch lines 910 can include first touch electrodes 911 and first bridge electrodes 912. The first bridge electrodes 912 can electrically connect between the first touch electrodes 911. For example, each of the driving touch lines 910 can include the first touch electrodes 911 connected in a third direction by the first bride electrodes 912. The third direction can be a direction different from the first direction X and the second direction Y. Each of the sensing touch lines 920 can include second touch electrodes 921 and second bridge electrodes 922. The second touch electrodes 921 can be disposed between the first touch electrodes 911. For example, the first touch electrodes 911 and the second touch electrodes 912 can be arranged to stagger each other. Thus, in the display apparatus according to another embodiment of the present disclosure, the touch of the user and/or the tool can be sensed by using the driving touch lines 910 and the sensing touch lines 920.

The second bridge electrodes 922 can electrically connect between the second touch electrodes 921. The second touch electrodes 921 can be connected in a fourth direction different from the third direction. For example, the second touch electrodes 921 can be connected by the second bridge electrodes 922 in a direction perpendicular to the first touch electrodes 911. Each of the sensing touch lines 920 can intersect one of the driving touch lines 910. Each of the second bridge electrodes 922 can intersect one of the first bridge electrodes 912. The second bridge electrodes 922 can be disposed on a different layer from the first bridge electrodes 912. For example, the second bridge electrodes 922 can be disposed between the first barrier pattern 510 and the optical insulating layer 600, and the first touch electrodes 911, the second touch electrodes 921 and the first bridge electrodes 912 can be disposed between the optical insulating layer 600 and the lens passivation layer 800.

The first touch electrodes 911, the first bridge electrodes 912, the second touch electrodes 921 and the second bridge electrodes 922 can include a conductive material. The first touch electrodes 911, the first bridge electrodes 912, the second touch electrodes 921 and the second bridge electrodes 922 can include a material having a relative low resistance. For example, the first touch electrodes 911, the first bridge electrodes 912, the second touch electrodes 921 and the second bridge electrodes 922 can include a metal, such as copper (Cu), molybdenum (Mo), titanium (Ti) and Tantalum (Ta). A thickness difference due to the first touch electrodes 911, the second touch electrodes 921 and the first bridge electrodes 912 can be removed by the lens passivation layer 800.

The touch sensor Cm can be disposed within the active area AA. The first touch electrodes 911, the first bridge electrodes 912, the second touch electrodes 921 and the second bridge electrodes 922 can be disposed outside the emission area R-EA, G-EA and B-EA defined in each pixel area PA. For example, the first touch electrodes 911, the first bridge electrodes 912, the second touch electrodes 921 and the second bridge electrodes 922 can overlap the bank insulating layer 160. Thus, in the display apparatus according to another embodiment of the present disclosure, the travelling direction of the light emitted from the light-emitting device 300 of each pixel area PA can be limited by the first touch electrodes 911, the first bridge electrodes 912, the second touch electrodes 921 and the second bridge electrodes 922. For example, in the display apparatus according to another embodiment of the present disclosure, the first touch electrodes 911, the first bridge electrodes 912 and the second touch electrodes 921 disposed between the optical insulating layer 600 and the lens passivation layer 800 can function as the second barrier pattern. Therefore, in the display apparatus according to another embodiment of the present disclosure, a process of limiting the travelling direction of the light emitted from the light-emitting device 300 of each pixel area PA can be simplified. That is, in the display apparatus according to another embodiment of the present disclosure, the production energy can be reduced by process optimization.

The pixel lens 700 of each pixel area PA can be disposed between the first touch electrodes 911, the first bridge electrodes 912 and the second touch electrodes 921. Thus, in the display apparatus according to another embodiment of the present disclosure, the travelling direction of the light emitted from the light-emitting device 300 of each pixel area PA can be limited by the touch sensor Cm, and the light extraction efficiency can be improved by the pixel lens 700 on each pixel area PA.

The display apparatus according to the embodiment of the present disclosure is described that a single emission area R-EA, G-EA and B-EA can be defined in each pixel area PA. However, in the display apparatus according to another embodiment of the present disclosure, each of the pixel areas PA can include a plurality of emission areas R-EA, G-EA and B-EA. For example, in the display apparatus according to another embodiment of the present disclosure, each of the pixel areas R-PA, G-PA and B-PA can include a first sub-pixel SP1 and a second sub-pixel SP2, each of the first sub-pixel SP1 and the second sub-pixel SP2 in each pixel area PA can include at least one emission area R-EA1, R-EA2, G-EA1, G-EA2, B-EA1 and B-EA2, as shown in FIG. 12. The second sub-pixel SP2 of each pixel area R-PA, G-PA and B-PA can realize a same color as the first sub-pixel SP1 of the corresponding pixel area R-PA, G-PA and B-PA. For example, each of the pixel area R-PA, G-PA and B-PA can be one of a red pixel area R-PA in which the first sub-pixel SP1 and the second sub-pixel SP2 realize red color, a green pixel area G-PA in which the first sub-pixel SP1 and the second sub-pixel SP2 realize green color, and a blue pixel area B-PA in which the first sub-pixel SP1 and the second sub-pixel SP2 realize blue color.

The number of the emission area R-EA2, G-EA2 and B-EA2 in the second sub-pixel SP2 of each pixel area R-PA, G-PA and B-PA can be different from the number of the emission area R-EA1, G-EA1 and B-EA1 in the first sub-pixel SP1 of the corresponding pixel area R-PA, G-PA and B-PA. For example, two first green emission area G-EA1 can be defined in the first sub-pixel SP1 of the green pixel area G-PA, and one second green emission area G-EA2 can be defined in the second sub-pixel SP2 of the green pixel area G-PA. Three first blue emission area B-EA1 can be defined in the first sub-pixel SP1 of the blue pixel area B-PA, and one second blue emission area B-EA2 can be defined in the second sub-pixel SP2 of the blue pixel area B-PA. One first red emission area R-EA1 can be defined in the first sub-pixel SP1 of the red pixel area R-PA, and one second red emission area R-EA2 can be defined in the second sub-pixel SP2 of the red pixel area R-PA.

The first sub-pixel SP1 and the second sub-pixel SP2 of each pixel area R-PA, G-PA and B-PA can be selectively operated. For example, the first sub-pixel SP1 of each pixel area R-PA, G-PA and B-PA can operate simultaneously with the first sub-pixels SP1 of adjacent pixel areas R-PA, G-PA and B-PA, and the second sub-pixel SP2 of each pixel area R-PA, G-PA and B-PA can operate simultaneously with the second sub-pixels SP2 of adjacent pixel areas R-PA, G-PA and B-PA. The second sub-pixel SP2 of each pixel area R-PA, G-PA and B-PA can have a viewing angle different from the first sub-pixel SP1 of each pixel area R-PA, G-PA and B-PA. For example, the second emission area R-EA2, G-EA2 and B-EA2 defined in the second sub-pixel SP2 of each pixel area R-PA, G-PA and B-PA can have a plane shape different from the first emission area R-EA1, G-EA1 and B-EA1 defined in the first sub-pixel SP1 of the corresponding pixel area R-PA, G-PA and B-PA. A plane of the first emission area R-EA1, G-EA1 and B-EA1 defined in each pixel area R-PA, G-PA and B-PA can have a circular shape, and a plane of the second emission area R-EA2, G-EA2 and B-EA2 defined in each pixel area R-PA, G-PA and B-PA can have a bar shape extending in a direction. Thus, in the display apparatus according to another embodiment of the present disclosure, the second sub-pixel SP2 of each pixel area R-PA, G-PA and B-PA can have a viewing angle wider than the first sub-pixel SP1 of the corresponding pixel area R-PA, G-PA and B-PA. That is, in the display apparatus according to another embodiment of the present disclosure, the image that is not recognized by the people disposed around the user can be realized by the first sub-pixel SP1 of each pixel area R-PA, G-PA and B-PA, and the image shared with the people disposed around the user can be realized by the second sub-pixel SP2 of each pixel area R-PA, G-PA and B-PA. Therefore, in the display apparatus according to another embodiment of the present disclosure, the image in a narrow viewing angle mode or an image in a wide viewing angle mode can be selectively provided by the first sub-pixel SP1 and the second sub-pixel SP2 of each pixel area R-PA, G-PA and B-PA.

The pixel lens 700 of each pixel area R-PA, G-PA and B-PA can include a first optical lens 701 disposed on the first emission area R-EA1, G-EA1 and B-EA1 of the corresponding pixel area R-PA, G-PA and B-PA, and a second optical lens 702 disposed on the second emission area R-EA2, G-EA2 and B-EA2 of each pixel area R-PA, G-PA and B-PA. A plane of the first optical lens 701 in each pixel area R-PA, G-PA and B-PA can have a shape corresponding to a plane of the first emission area R-EA1, G-EA1 and B-EA1 of the corresponding pixel area R-PA, G-PA and B-PA. For example, the plane of the first optical lens 701 in each pixel area R-PA, G-PA and B-PA can have a circular shape. The second optical lens 702 in each pixel area R-PA, G-PA and B-PA can include a first lens region having a bar-shaped plane extending in a direction and a second lens region having a plane shape extending from the first lens region. An end portion of the second lens region in each pixel area R-PA, G-PA and B-PA can have a curved plane shape having a larger curvature than an end portion of the second emission area R-EA2, G-EA2 and B-EA2 in the corresponding pixel area R-PA, G-PA and B-PA. Thus, in the display apparatus according to another embodiment of the present disclosure, the luminance of the light emitted from the second emission area R-EA2, G-EA2 and B-EA2 in each pixel area R-PA, G-PA and B-PA can be improved. Therefore, in the display apparatus according to another embodiment of the present disclosure, the degree of freedom for the configuration of each pixel area R-PA, G-PA and B-PA can be improved.

In the result, the display apparatus according to the embodiments of the present disclosure can comprise the light-emitting device, the first barrier pattern, the optical insulating layer, the second barrier pattern and the pixel lens, which are disposed on the device substrate, wherein the light-emitting device and the pixel lens can overlap the emission area, wherein the first barrier pattern and the second barrier pattern can extend in a first direction, and wherein a plane of an end portion of the pixel lens toward the first direction can have a curved shape. Thus, in the display apparatus according to the embodiments of the present disclosure, the travelling direction of the light emitted from the light-emitting device can be limited by the first barrier pattern and the second barrier pattern, and the amount of the light provided to the user through the pixel lens can be increased. Thereby, in the display apparatus according to the embodiments of the present disclosure, the quality of the image recognized by the user can be improved. And, in the display apparatus according to the embodiments of the present disclosure, the low power driving can be possible, and the power consumption can be reduced.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a device substrate including an emission area and a non-emission area;
a light-emitting device on the emission area of the device substrate;
a first barrier pattern on the light-emitting device, the first barrier pattern overlapping with the non-emission area;
an optical insulating layer on the light-emitting device and the first barrier pattern, the optical insulating layer overlapping with the emission area and the non-emission area;
a second barrier pattern on the optical insulating layer, the second barrier pattern overlapping with the first barrier pattern; and
a pixel lens on the optical insulating layer, the pixel lens including a first lens region overlapping with the emission area and second lens regions extending from the first lens region in a first direction,
wherein the first barrier pattern and the second barrier pattern extend in a first direction,
wherein each of an end portion of each second lens region and an end portion of the emission area toward the first direction includes a region disposed outside the first barrier pattern and the second barrier pattern, and
wherein a plane of the end portion of the second lens region toward the first direction has a larger curvature than a plane of the end portion of the emission area toward the first direction.

2. The display apparatus according to claim 1, wherein the second lens region includes a same material as the first lens region.

3. The display apparatus according to claim 1, wherein a cross-section of the first lens region in the first direction has a constant thickness,
wherein a cross-section of the second lens region in the first direction has a curved shape, and
wherein the maximum thickness of the cross-section of the second lens region in the first direction is a same as the thickness of the cross-section of the first lens region in the first direction.

4. The display apparatus according to claim 3, wherein a length of the first lens region in a second direction perpendicular to the first direction is constant, and
wherein the maximum length of the second lens region in the second direction is a same as the length of the first lens region in the second direction.

5. The display apparatus according to claim 1, wherein a plane of the emission area and a plane of the first lens region has a bar shape extending in the first direction.

6. The display apparatus according to claim 5, wherein a side of the first lens region extending in the first direction overlaps the second barrier pattern.

7. The display apparatus according to claim 1, wherein the second barrier pattern includes a different material from the first barrier pattern.

8. The display apparatus according to claim 7, wherein the second barrier pattern includes a conductive material.

9. A display apparatus comprising:
a bank insulating layer on a device substrate, the bank insulating layer defining an emission area;
a light-emitting device on the emission area of the device substrate;
a first barrier pattern extending in a first direction on the bank insulating layer;
an optical insulating layer on the light-emitting device and the bank insulating layer, the optical insulating layer covering the first barrier pattern;
a second barrier pattern on the optical insulating layer, the second barrier pattern extending adjacent to the first barrier pattern; and
a pixel lens disposed on the optical insulating layer of the emission area, the pixel lens having a greater size than the emission area,
wherein an end portion of the pixel lens and an end portion of the emission area toward the first direction are spaced apart from the first barrier pattern and the second barrier pattern, and
wherein in a plan view, the maximum distance between the pixel lens and the emission area in the first direction is larger than the maximum distance between the pixel lens and the emission area in a second direction transverse to the first direction.

10. The display apparatus according to claim 9, wherein a length of the emission area in the second direction is smaller than a length of the emission area in the first direction.

11. The display apparatus according to claim 9, wherein the pixel lens includes a first lens region overlapping with emission area and a second lens region disposed side by side with the first lens region,
wherein the first lens region and the second lens region include a region overlapping with the second barrier pattern, and
wherein a portion of the first lens region overlapping with the second barrier pattern has a smaller size than a portion of the second lens region overlapping with the second barrier pattern.

12. The display apparatus according to claim 11, wherein the second lens region is in contact with the first lens region.

13. The display apparatus according to claim 11, wherein a plane of a portion of the second lens region overlapping with the second barrier pattern has a curved shape.

14. The display apparatus according to claim 11, wherein the maximum length of the second lens region in the second direction is 120% to 140% with respect to the maximum length of the first lens region in the second direction.

15. The display apparatus according to claim 9, wherein a plane of the pixel lens has a shape that is symmetrical with respect to the center portion of the emission area.

16. The display apparatus according to claim 9, wherein the second barrier pattern extends parallel to the first barrier pattern.

17. The display apparatus according to claim 9, wherein the second direction is perpendicular to the first direction.
